(19) United States
(12) Patent Application Publication
(10) Pub. No.: US 2017/0218498 A1
(43) Pub. Date: Aug. 3, 2017

(54) PROCESS FOR DEPOSITING METAL OR METALLOID CHALCOGENIDES

(71) Applicant: AGENCY FOR SCIENCE, TECHNOLOGY AND RESEARCH, Singapore (SG)

(72) Inventors: Jianwei CHAI, Singapore (SG); Junguang TAO, Singapore (SG); Shijie WANG, Singapore (SG)

(21) Appl. No.: 15/328,896

(22) PCT Filed: Jul. 23, 2015
(86) PCT No.: PCT/SG2015/050231

§ 371 Date: Jan. 24, 2017

(30) Foreign Application Priority Data
Jul. 24, 2014 (SG) 10201404379Q

(51) Int. Cl. C23C 14/00; C23C 14/06; H01L 21/02; C23C 14/35

(52) U.S. Cl. CPC C23C 14/0057; C23C 14/35; C23C 14/0623; H01L 21/02568; H01L 21/02631

(57) ABSTRACT

The instant invention provides a process for making metal or metalloid dichalcogenides from a metal or metalloid and elemental chalcogen using magnetron sputtering. The process may comprise the steps of directing sputtering gas ions at a metal or metalloid target, reacting the ejected metal or metalloid atoms from the target surface with an elemental chalcogen vapor and assembling the metal or metalloid dichalcogenides on a substrate. It can be used to make thin films of the dichalcogenides which have a use in layered semiconductor devices. The process of the invention is suitable for upscaling to potentially make the films on a wafer level. Films on large areas with high uniformity have for instance been obtained utilizing the reaction of the metal or metalloid in an ambient of vaporized chalcogen under controlled conditions and with low growth rates. The process of the invention can be used to deposit two dimensional channels as part of field effect transistors. The materials made with the process in general can have a use in nanoelectronics as a catalyst, as a photo-detector, photovoltaic or photocatalyst.

### TECHNICAL FIELD

The present invention generally relates to a process for making metal or metalloid chalcogenides as nanostructured materials. The present invention also relates to the use of the process to create one or multiple 2D monolayers of the metal or metalloid chalcogenide. It also relates to the use of the metal or metalloid chalcogenides in a layered semiconductor device such as a field effect transistor.

### BACKGROUND ART

Recently, transition-metal dichalcogenides (TMD), a class of layered semiconductor, have received increased interests due to their wide applications in nanoelectronics, catalyst, photo-detectors, photovoltaic and photocatalyst. Among them, molybdenum disulphide (MoS₂) was a prototype for this class and has been most widely investigated both experimentally and theoretically. Monolayer MoS₂ presents a direct band gap (1.8 eV) at the K point of the Brillouin zone, while in few-layer and bulk counterpart an indirect band gap (1.2 eV) is observed. With the small band gap energy and high light absorption in the visible light range, MoS₂ could be suitable for applications in effective photovoltaic and photocatalysts under visible light. A monolayer MoS₂ transistor has shown a high current on-off ratio of 1×10⁹, high current density and the negligible OFF current using mechanically exfoliated flakes from bulk geological samples. This indicates that the sensitivity of MoS₂-based field effect transistors (FETs) can be significantly improved which is comparable to silicon-based transistors and better than that from graphene ribbons. In addition, logic circuits and amplifiers have also been demonstrated recently using monolayer MoS₂. The structure of MoS₂ is formed by covalently bonded S—Mo—S two-dimensional (2D) hexagonal atomic trilayer, which weakly bounds with neighboring layers via van der Waals forces. In each layer, the electrons and holes are intrinsically confined in the 2-dimensional layer, which gives rise to many unusual physical and chemical properties and offers the advantages of superior vertical scaling for a transistor topology. The potential of these materials for low-cost flexible or transparent electronics that could revolutionize technology is also very high, which are valuable for demonstrating the promise of MoS₂ devices. With these advantages and potential applications, large area of MoS₂ layers manufacturing with an easily controlled manner is greatly desired.

Monolayer of MoS₂ was first obtained by the mechanical exfoliation technique as commonly used for graphene. However, the traditional mechanical exfoliation method limits its usefulness in a commercially viable device. Later, attempts to develop more scalable techniques include solution-based exfoliation, epitaxial growth, and soft sulphurization, physical vapor deposition, sulphurization of molybdenum oxides, hydrothermal synthesis, and electrochemical lithiation process. Recently, it is reported that large scale MoS₂ can be obtained via chemical vapor deposition (CVD) using a Mo film (or MoO₃ powder) and sulphur powder as the reactants. However, all the previous used methods are not capable to integrate with device fabrication and MoS₂ monolayer resulted from those chemical methods will co-exist with some by-products. As the properties of MoS₂ materials strongly depend on the layer number, the uniformity and controllability are extremely important for the improvement of device performance.

Similar to graphene, the practical application based on such 2D semiconducting materials also requires the facile procedures for low-cost and high-yield preparation of the materials.

There is therefore a need to provide a process for the production of metal or metalloid chalcogenides that overcomes, or at least ameliorates, one or more of the disadvantages described above.

### SUMMARY OF INVENTION

According to a first aspect, there is provided a process for making metal or metalloid chalcogenides from a metal or metalloid and an elemental chalcogen using magnetron sputtering.

In one embodiment, the sputtering process may comprise the steps of a) directing sputtering gas ions at a target comprising a metal or metalloid, b) reacting the ejected metal or metalloid atoms from the target surface with an elemental chalcogen vapor and c) assembling the metal or metalloid chalcogenides on a substrate. This process may involve a chemical reaction between the ejected metal or metalloid atoms and the chalcogen and may therefore additionally be referred to as a reactive sputtering process. Preferably, the reactive gas comprises an elemental chalcogen vapor.

Advantageously the process according to the invention allows producing metal or metalloid chalcogenide films in a controlled way. Films can be grown uniformly over large areas in the form of a few layers of the metal or metalloid chalcogenide. The method can be scaled up to large area sample preparation. In this way it is compatible with industry mass production techniques on wafer level.

In another embodiment, the sputtering may be performed in an apparatus comprising: i) a vacuum deposition chamber, ii) a sputtering target comprising the metal or metalloid, iii) a reservoir of elemental chalcogen optionally linked to a vaporizer, iv) a power source to effect ejection of the metal or metalloid and v) a substrate on which the deposition of the metal or metalloid chalcogenide occurs.

Advantageously, the use of such apparatus allows effectively reacting the elemental chalcogen with the metal or metalloid during the sputtering to form the films. In the apparatus the vaporization of the elemental chalcogen can be further controlled by the optional use of a suitable vaporizer. Different crystal structure imperfections may be introduced as compared to known methods. Advantageously, the sulphur can be vaporized in a suitable manner using such apparatus when temperatures and partial vapor pressure of the elemental chalcogen are controlled. Advantageously, the sputtering gas is provided with a fixed pressure of about 1.0×10⁻⁴ to 3.0×10⁻³ mbar.

The deposition in the sputtering process may be performed with a substrate temperature of between about 300° C. and 1000° C. Advantageously, a high temperature leads to the deposition of the desired films.

In another embodiment, the chalcogen may be vaporized by heating. The vaporized chalcogen may preferably produce a partial pressure of about 1.0 to 9.0×10⁻⁷ mbar. Advantageously, a controlled vaporization by heating and a controlled partial pressure of the chalcogen can be utilized for optimal deposition for various applications.

More advantageously, the process as disclosed above may be performed using a DC power source, with a DC power of less than 10 W for the sputtering. Advantageously, the growth rate of the layers can be controlled with high precision by the use of a low power source for sputtering.

Advantageously, a very low partial argon pressure and a low power source used in the magnetron sputtering process allows to grow materials at a very low rate in a controllable chalcogen vapor environment, which can allow the control of 2D growth down to monolayers with lower defects.

The process as disclosed herein may comprise the production of a transition metal dichalcogenide.

In a second aspect, there is provided the use of the process to create one or multiple 2D monolayers of the transitional chalcogenide on a substrate. Advantageously, the 2D monolayers can be produced in high uniformity and precision.

In a third aspect, there is provided a metal or metalloid chalcogenide obtainable by the process as disclosed above. The chalcogenide can advantageously be grown on various substrates with a defined orientation (e.g. c-axis of MoS₂ perpendicular to the substrate surface) and high quality.

In a fourth aspect, there is provided use of the metal or metalloid chalcogenide as disclosed above in a layered semiconductor device, such as a field effect transistor. Advantageously, the obtained field effect transistors can show an improved performance when being applied in photovoltaic or photocatalyst applications.

In a fifth aspect, there is provided use of the metal or metalloid chalcogenide as disclosed above in nanoelectronics, as a catalyst, as a photo-detector, photovoltaic or photocatalyst.

### DEFINITIONS

The following words and terms used herein shall have the meaning indicated:

The term ‘transition metal’ is to be interpreted broadly to include any element in which the filling of the outermost shell to eight electrons within a periodic table is interrupted to bring the penultimate shell from 8 to 18 or 32 electrons. Transition elements may include, without limitation, scandium, titanium, vanadium, chromium, manganese, iron, cobalt, nickel, copper, zinc, ytterbium, zirconium, niobium, molybdenum, silver, lanthanum, hafnium, tantalum, tungsten, rhenium, rare-earth elements, cerium, praseodymium, neodymium, promethium, samarium, europium, gadolinium, terbium, dysprosium, holmium, erbium, thulium, yttrium, lutetium, and rhodium. Included in this definition are post-transition metals, which may refer to the metallic elements in the periodic table located between the transition metals (to their left) and the metalloids (to their right). These elements may include gallium, indium and thallium; tin and lead; and bismuth, cadmium and mercury; and aluminium.

The term ‘2D monolayer’ or ‘2-dimensional monolayer’ is to be interpreted broadly to include substantially flat, two dimensional layers of the chalcogenide on an atomic level. Flat thin films (“2D films”) of such layers may have the thickness of one or multiple monolayers of the metal or metalloid chalcogenide. It may typically have a thickness of up to 10 nm.

The term ‘inert gas’ is to be interpreted broadly to include any gas which does not form chemical bonds when used in magnetron sputtering. Exemplary inert gases include noble gases but may include other gases so long as no chemical bonds are formed.

The term ‘chalcogen’ is to be interpreted broadly to include Group VIA elements. Group VIA elements may include sulphur, selenium and tellurium or mixtures thereof.

The term ‘film’ is to be interpreted broadly to include a thin, commonly flexible, form of a material, which may be for example a layer on a surface of a substrate.

The term ‘substrate’ is to be interpreted broadly to include materials upon which one or more layers of the metal or metalloid chalcogenide may be deposited. The substrate may comprise any material, as long as it is stable under the conditions applied in the sputtering process.

The term ‘target’ is to be interpreted broadly to include materials from which atoms may be ejected to form a coating on a substrate. The ejected atoms from the target may engage in subsequent reactions to form covalent bonds. In the present context, the target may include, but is not limited to, metals or metalloids or materials comprising metals or metalloids or materials comprising transition metals.

The term ‘transition metal dichalcogenide’ is to be interpreted broadly to include materials that comprise transition metals and Group VIA elements. There may be a covalent bond between the transition metal and the atoms of the dichalcogenide.

The term ‘magnetron sputtering’ is to be interpreted broadly to include the ejection of atoms from a surface as a consequence of ions impacting that surface and, in some manner, imparting enough energy to some surface atoms to overcome binding energies and cause these atoms to be ejected. The term may include ‘reactive sputtering’.

The term ‘vapor’, ‘vaporized’ or ‘vaporizer’ is to be interpreted broadly to include a gaseous phase of the element. As used herein, it refers to the gaseous phase of the chalcogenide, wherein the concentration of the chalcogenide in the atmosphere may be irrelevant.

The word “substantially” does not exclude “completely” e.g. a composition which is “substantially free” from Y may be completely free from Y. Where necessary, the word “substantially” may be omitted from the definition of the invention.

Unless specified otherwise, the terms “comprising” and “comprise”, and grammatical variants thereof, are intended to represent “open” or “inclusive” language such that they include recited elements but also permit inclusion of additional, unrecited elements.

As used herein, the term “about”, in the context of concentrations of components of the formulations, typically means ±5% of the stated value, more typically ±4% of the stated value, more typically ±3% of the stated value, more typically, ±2% of the stated value, even more typically ±1% of the stated value, and even more typically ±0.5% of the stated value.

Throughout this disclosure, certain embodiments may be disclosed in a range format. It should be understood that the description in range format is merely for convenience and brevity and should not be construed as an inflexible limitation on the scope of the disclosed ranges. Accordingly, the description of a range should be considered to have specifically disclosed all the possible sub-ranges as well as individual numerical values within that range. For example, description of a range such as from 1 to 6 should be considered to have specifically disclosed sub-ranges such as from 1 to 3, from 1 to 4, from 1 to 5, from 2 to 4, from 2 to 6, from 3 to 6 etc., as well as individual numbers within that range, for example, 1, 2, 3, 4, 5, and 6. This applies regardless of the breadth of the range.

Certain embodiments may also be described broadly and generically herein. Each of the narrower species and subgeneric groupings falling within the generic disclosure also form part of the disclosure. This includes the generic description of the embodiments with a proviso or negative limitation removing any subject matter from the genus, regardless of whether or not the excised material is specifically recited herein.

### DETAILED DISCLOSURE OF EMBODIMENTS

Exemplary, non-limiting embodiments of a process for the production of a metal or metalloid chalcogenide, will now be disclosed.

There is provided a one-step process for making metal chalcogenides from a metal or metalloid and an elemental chalcogen using magnetron sputtering. The term sputtering refers to the ejection of atoms from the surface of a target as a consequence of ions impacting that surface and, in some manner, imparting enough energy to some surface atoms to overcome binding energies and cause these atoms to be ejected. Sputtering is most commonly used as a method of depositing coatings onto other surfaces.

The sputtering according to the invention preferably provides for a target subjected to ion bombardment (“ion-beam sputtering”). Additionally, the atoms ejected from the target may engage in chemical reactions (“reactive sputtering”) with a reactive gas of the elemental chalcogen present in the process (preferably a vaporized chalcogen) and thus the deposited coating will have a different chemical composition from the target. The items to be coated, generally referred to as the substrates, are preferably placed in locations (with respect to the ion bombarded surface) in which their surfaces will intercept the greatest flux of ejected atoms, and thus be coated. In magnetron sputtering, magnetic fields are employed to help confine electrons which generate the plasma which is the source of bombarding ions. This confinement greatly increases both the sputtering rate and the system efficiency by minimizing the loss of both ions and ionizing electrons.

The process may be applicable to large scale production of the metal or metalloid chalcogenides. It may be applicable to conventional present semiconductor fabrication processes. It may be applicable for the fabrication of 8 inch wafers.

Thus, in one embodiment, the process as disclosed above may comprise the steps of a) directing sputtering gas ions at a target comprising a metal or metalloid (ion-beam sputtering), b) reacting the ejected metal or metalloid atoms from the target surface with an elemental chalcogen vapor (reactive sputtering) and c) assembling the metal or metalloid chalcogenides on a substrate.

Sputtering may be conducted in a vacuum deposition chamber and in the presence of an inert sputtering gas, such as argon, that may be maintained under very low pressure. The inert sputtering gas may form a plasma, which may contain a reactive gas, for example elemental chalcogen, optionally linked to a vaporizer. The material to be sputtered (referred to as the target) may be connected to the negative terminal of a DC power supply and may serve as a cathode. The positive terminal of the power supply may be connected to a separate anode structure or to the vacuum chamber itself, depending on the application. Deposition of the reaction product between the atoms originating from the target and atoms originating from the reactive gas, in the present context the metal or metalloid chalcogenide, may occur on a substrate.

The target is preferably a metal or metalloid.

Thus, in one embodiment, the sputtering process may be performed in an apparatus comprising: i) a vacuum deposition chamber, ii) a sputtering target comprising the metal or metalloid, iii) a reservoir of elemental chalcogen optionally linked to a vaporizer, iv) a power source to effect the ejection of metal or metalloid atoms and v) a substrate on which the deposition of the metal or metalloid chalcogenide occurs. Illustrative in this context is FIG. 1, in which an exemplary apparatus is shown. It consists of a chamber, which is connected to a pump for production of a vacuum. Introduced into this chamber is a sputtering target, from which atoms can be ejected. On the opposite side and in a straight line of the sputtering target is a substrate, on which the deposition of the metal or metalloid chalcogenide may occur. Additionally connected to the vacuum chamber is a reservoir, containing the elemental chalcogen, provided as a powder according to a preferred embodiment, which is wrapped in heating tape. This effects small amounts of the chalcogen to evaporate and, through a leaking valve, reach the vacuum chamber in a vaporized state. The sputtering gas, in the example shown as Argon, may be ionized and thereby ejecting atoms from the sputtering target. The ejected atoms originating from the sputtering may react with the chalcogen and the reaction product may self-assemble on the substrate, thereby forming a thin film, optionally a monolayer. The process can be used to create such monolayer, but also two layers, three layers, four layers, five layers, six layers, seven layers or multiple layers of small number, but controlled number on the substrate by altering the power of the ion beam or the deposition time.

In one embodiment, the process as disclosed above may be performed with a substrate temperature of between about 300° C. and about 1000° C., or between about 300° C. and about 900° C., or between about 300° C. and about 800° C., or between about 300° C. and about 700° C., or between about 300° C. and about 600° C., or between about 300° C. and about 500° C., or between about 300° C. and about 400° C., or between about 400° C. and about 1000° C., or between about 500° C. and about 1000° C., or between about 600° C. and about 1000° C., or between about 700° C. and about 1000° C., or between about 800° C. and about 1000° C., or between about 900° C. and about 1000° C., or between about 400° C. and about 900° C., or between about 500° C. and about 800° C., or between about 600° C. and about 800° C., or preferably between about 650° C. and about 750° C., or at about 300° C., at about 400° C., at about 500° C., at about 600° C., at about 700° C., at about 800° C., at about 00° C., or at about 1000° C. A temperature of about 700° C. can be particularly mentioned. For achieving a best uniformity it may be desired to control the temperature in a small range.

In one embodiment, the chalcogen may be vaporized by heating. The heating may be effected using a variety of heat sources, which may include, but are not limited to, heating tape, oil bath, sand bath, oven or water bath. Advantageously, in one embodiment, the heating of the chalcogen is performed by using wrapped heating tape.

The heating process may result in the vaporized chalcogen producing a partial pressure in the vacuum chamber during the sputtering.

Thus, in one embodiment, the vaporized chalcogen produces a partial pressure of about 1.0 to about 9.0×10⁻⁷ mbar, or about 2.0 to about 9.0×10⁻⁷ mbar, or about 3.0 to about 9.0×10⁻⁷ mbar, or about 4.0 to about 9.0×10⁻⁷ mbar, or about 5.0 to about 9.0×10⁻⁷ mbar, or about 6.0 to about 9.0×10⁻⁷ mbar, or about 7.0 to about 9.0×10⁻⁷ mbar, or about 8.0 to about 9.0×10⁻⁷ mbar, or about 1.0 to about 8.0×10⁻⁷ mbar, or about 1.0 to about 7.0×10⁻⁷ mbar, or about 1.0 to about 6.0×10⁻⁷ mbar, or about 1.0 to about 5.0×10⁻⁷ mbar, or about 1.0 to about 4.0×10⁻⁷ mbar, or about 1.0 to about 3.0×10⁻⁷ mbar, or about 1.0 to about 2.0×10⁻⁷ mbar, or about 2.0 to about 8.0×10⁻⁷ mbar, or about 3.0 to about 7.0×10⁻⁷ mbar, or about 4.0 to about 6.0×10⁻⁷ mbar, or of about 1.0×10⁻⁷ mbar, of about 2.0×10⁻⁷ mbar, of about 3.0×10⁻⁷ mbar, of about 4.0×10⁻⁷ mbar, of about 5.0×10⁻⁷ mbar, of about 6.0×10⁻⁷ mbar, of about 7.0×10⁻⁷ mbar, of about 8.0×10⁻⁷ mbar, or of about 9.0×10⁻⁷ mbar. A range of about 3.0 to about 5.0×10⁻⁷ mbar can be particularly mentioned. It can be critical for optimal performance to control this partial gas pressure carefully using for instance a residual gas analyser (RGA). As a residual gas analyse a small and usually rugged mass spectrometer, typically designed for process control in vacuum systems, can be used.

In one embodiment, the deposition chamber may comprise a sputtering gas. As detailed further above, sputtering may be conducted in the presence of a sputtering gas, such as an inert gas, that advantageously may be maintained under very low pressure.

The sputtering gas may be provided with a fixed pressure of about 1.0×10⁻⁴ to about 3.0×10⁻³ mbar, or about 1.0×10⁻⁴ to about 2.0×10⁻³ mbar, or about 1.0×10⁻⁴ to about 1.0×10⁻³ mbar, or about 1.0×10⁻⁴ to about 9.0×10⁻⁴ mbar, or about 1.0×10⁻⁴ to about 8.0×10⁻⁴ mbar, or about 1.0×10⁻⁴ to about 7.0×10⁻⁴ mbar, or about 1.0×10⁻⁴ to about 6.0×10⁻⁴ mbar, or about 1.0×10⁻⁴ to about 5.0×10⁻⁴ mbar, or about 1.0×10⁻⁴ to about 4.0×10⁻⁴ mbar, or about 1.0×10⁻⁴ to about 3.0×10⁻⁴ mbar, or about 1.0×10⁻⁴ to about 2.0×10⁻⁴ mbar, or about 2.0×10⁻⁴ to about 3.0×10⁻³ mbar, or about 3.0×10⁻⁴ to about 3.0×10⁻³ mbar, or about 4.0×10⁻⁴ to about 3.0×10⁻³ mbar, or about 5.0×10⁻⁴ to about 3.0×10⁻³ mbar, or about 6.0×10⁻⁴ to about 3.0×10⁻³ mbar, or about 7.0×10⁻⁴ to about 3.0×10⁻³ mbar, or about 8.0×10⁻⁴ to about 3.0×10⁻³ mbar, or about 9.0×10⁻⁴ to about 3.0×10⁻³ mbar, or about 1.0×10⁻³ to about 3.0×10⁻³ mbar, or about 2.0×10⁻³ to about 3.0×10⁻³ mbar, or about 2.0×10⁻⁴ to about 2.0×10⁻³ mbar, or about 3.0×10⁻⁴ to about 1.0×10⁻³ mbar, or about 4.0×10⁻⁴ to about 9.0×10⁻⁴ mbar, or about 5.0×10⁻⁴ to about 8.0×10⁻⁴ mbar, or about 6.0×10⁻⁴ to about 7.0×10⁻⁴ mbar, or at about 1.0×10⁻⁴, at about 2.0×10⁻⁴, at about 3.0×10⁻⁴, at about 4.0×10⁻⁴, at about 5.0×10⁻⁴, at about 6.0×10⁻⁴, at about 7.0×10⁻⁴, at about 8.0×10⁻⁴, at about 9.0×10⁻⁴, at about 1.0×10⁻³ mbar, at about 2.0×10⁻³ mbar, or at about 3.0×10⁻³ mbar. A range of about 6.2 to 6.6×10⁻⁴ mbar may be particularly mentioned.

In one embodiment, the sputtering gas may comprise an inert gas. The inert gas may be chosen from any gas, which does not from covalent bonds with any of the reaction partners of the above disclosed process. It may typically be chosen from the group of noble gases. It may be chosen depending on the atomic weight of the target, which usually is close to the atomic weight of the sputtering gas, so for sputtering light elements neon is preferable, while for heavy elements krypton or xenon are used.

In one embodiment, the inert gas may comprise a noble gas, such as argon, neon, xenon, and krypton. In particular, it may comprise argon. Advantageously, argon may be supplied at a partial pressure in a range of about 6.2 to 6.6×10⁻⁴ mbar.

In one embodiment, the power source to effect ejections of the metal or metalloid atoms may be selected from the power sources including, but not limited to, DC power and RF power. It may be a DC power source. It may be a RF power source.

Advantageously, there is provided a DC power of less than 10 W for the sputtering. A low DC current may be particularly suitable for a low growth rate of the metal or metalloid chalcogenide. This in turn may ensure an optimal degree of control over the sputtering process, which may result in the desired uniform and high quality modification of the metal or metalloid chalcogenide.

The growth rate can be chosen to achieve a deposition rate of about 0.1 to 5 nm, 0.1 to about 4 nm, or about 0.1 to about 3 nm, or about 0.2 to about 5 nm, or about 0.2 to about 4 nm, or about 0.2 to about 1 nm, or about 0.3 to about 3.5 nm, or about 0.4 to about 2 nm, or about 0.2 to about 0.8 nm per minute. Preferably it is 0.4 to 0.8 nm/min. A deposition rate of about 0.6 nm/min may be particularly mentioned.

In one embodiment, the substrate may be cleaned prior to the sputtering process. This may ensure sufficient purity of the metal or metalloid chalcogenide.

In a further embodiment, the cleaning may involve using acetone in an ultrasonic bath. The ultrasonic effect may de-attach any impurities off the surface of the substrate. Acetone may be preferably used as it has been found to remove most impurities well and it has the additional beneficial effect, that it evaporates quickly and does not itself represent an impurity.

In one embodiment, the substrate may include, but is not limited to, materials from the group consisting of glass, silicon, silicon oxides, metal, metal alloy, metal oxides and any mixture thereof. It may include any material, which is substantially stable under the reaction conditions. It may include materials or devices in need of a coating film consisting of a 2D monolayer or several well-defined layers of a metal or metalloid chalcogenide. The substrate may function as a substantially inert carrier.

In one embodiment, the substrate may include, but is not limited to, silicon or silicon oxide, optionally in amorphous phase and optionally hafnia-stabilized. Alternatively, it may include, but is not limited to, crystalline silicone. In this case the process may have a suitable application in wafer production.

In one embodiment, the substrate may include, but is not limited to, corundum, optionally aluminium oxide, preferably in a crystalline polymorphic phase α-Al₂O₃ There may be traces of other elements embedded in the aluminium oxide, for example iron, titanium, chromium, copper, or magnesium. Or it may be a gem stone, for example sapphire, emerald or ruby. It may be a single crystal of aluminium oxide. It may have a particular orientation, for example, it may be a c-plane sapphire [Al₂O₃(0001)].

Alternatively, in one embodiment, the substrate may include, but is not limited to, zirconia. It may be a cubic zirconia. It may be an oxide of zirconium. It may be a crystalline form of zirconia, or it may an amorphous form of zirconia. It may be stabilized by various other materials, to form stabilized zirconias, including, but not limited to calcia-, magnesia-, ceria-, hafnia or alumina-stabilized zirconias, or it may be partially stabilized zirconias. In a specific example, it may be yttria-stabilized zirconia (YSZ).

In one embodiment, the metal or metalloid chalcogenide may be a film on a substrate. The film may be in the form of a layer on a surface of the substrate. It may be a dry layer, as contrasted to a solution. The adhesive strength between the substrate and the film may be greater than the cohesive strength of the film. Thus if sufficient force is applied, the film may fail within its body rather than at the adhesive interface between the film and the substrate. This ensures a suitable hold between the surface of the substrate and the film.

In one embodiment, the film may include, but is not limited to, one or multiple monolayers of the metal or metalloid chalcogenides. The film therefore may comprise a monolayer, two layers, three layers, four, five layer, six layers, seven layers or a low number of multiple layers of the dichalcogenide. The thickness may vary according to the chalcogenides obtained in the process.

Advantageously, the film may have a thickness of about 0.5 to about 10 nm, or about 1.0 to about 10 nm, or about 2.0 to about 10 nm, or about 3.0 to about 10 nm, or about 4.0 to about 10 nm, or about 5.0 to about 10 nm, or about 6.0 to about 10 nm, or about 7.0 to about 10 nm, or about 8.0 to about 10 nm, or about 9.0 to about 10 nm, or about 0.5 to about 9.0 nm, or about 0.5 to about 8.0 nm, or about 0.5 to about 7.0 nm, or about 0.5 to about 6.0 nm, or about 0.5 to about 5.0 nm, or about 0.5 to about 4.0 nm, or about 0.5 to about 3.0 nm, or about 0.5 to about 2.0 nm, or about 0.5 to about 1.0 nm, or of about 0.5 nm, about 1.0 nm, about 2.0 nm, about 3.0 nm, about 4.0 nm, about 5.0 nm, about 6.0 nm, about 7.0 nm, about 8.0 nm, about 9.0 nm, or of about 10 nm.

The monolayers may have a thickness of about 0.3 to 2 nm, about 0.5 to 1 nm or about 0.6 to 0.8 nm. In the case of molybdenum dichalcogenide the thickness of the monolayer is usually about 0.75 nm±20%.

In some embodiments, the metal or metalloid has an oxidation state of +4 and the atomic ratio between the metal or metalloid and the chalcogen may be between about 1:1.75 to 2.05, or about 1:1.75 to 1.95, or about 1:1.75 to 1.85, or about 1:1.85 to 2.05, or about 1:1.95 to 2.05, or about 1:1.75, about 1:1.85, about 1:1.95, or about 1:2.05. Illustrative in respect of this embodiment may be FIG. 2. Exemplary for this process, FIG. 2 shows the core level spectra of X-ray photoelectron spectroscopy (XPS) of deposited molybdenum disulphide (MoS₂). It elucidates the molybdenum 3d and sulphur 2p spectra of MoS₂/sapphire (0001) [(a) and (b)], and MoS₂/YSZ (111) [(c) and (d)]. In this example, a few layers of MoS₂ were first grown on c-plane sapphire [Al₂O₃(0001)] and YSZ(111). As shown in FIG. 2 (a) and (c), the Mo 3d spectra on both substrates are almost identical, which can be fitted using two components at 229.81 and 232.94 eV, respectively, in agreement with reported values. As shown in FIG. 2 (b) and (d), the spin-orbital splitting for S 2p is well resolved which suggest the good film quality. On YSZ, the lower binding energy peaks at 161.31 eV and 159.21 eV come from the Y 3d_{3/2} and 3d_{5/2}orbitals. The atomic ratio between Mo and S is determined to be 1:2 from quantitative analysis of the XPS peaks.

In the metal or metalloid chalcogenide, the metal or metalloid may be prismatically coordinated by six surrounding chalcogen atoms and the c-axis may be perpendicular to the substrate. Illustrative in respect of this embodiment may be FIG. 3. Exemplary for the process, FIG. 3 shows a high-resolution X-ray diffraction result for MoS₂ film grown as compared to the bulk materials. The out-of-plane orientation of MoS₂film was determined to be (0001). The crystal structure of the film is confirmed to be 2H—MoS₂ phase on the substrates [Al₂O₃(0001)] and YSZ(111). In this phase, each molybdenum atom is prismatically coordinated by six surrounding sulphur atoms and it exhibits semiconducting behaviour. Supplementing the result of the 2H—MoS₂phase is also a Raman spectrum (FIG. 4), which additionally demonstrates that the films exhibit the correct phase and that they are in good quality.

The process as disclosed herein may comprise the production of a transition metal dichalcogenide.

As mentioned further above, in some embodiments, the deposited metal or metalloid chalcogenide may have semi-conducting properties. These properties may include, but are not limited to, passing current more easily in one direction than the other, showing variable resistance, and sensitivity to light or heat. This is especially the case for 2D monolayers or multiple layers of a small number of suitable chalcogenides, such as. MoS₂.

The metal or metalloid may include, but is not limited to, metals or metalloids such as indium, silicon, germanium, silver, tin, lead, bismuth, antimony, strontium, and any alloys or mixtures of these elements. A combination of these elements from different groups, or from the same group, may be used. The metal or metalloid may include, but is not limited to, transition metals. It may include, but is not limited to, aluminium, chromium, copper, tungsten and molybdenum. A combination of these elements from different groups, or from the same group, may be used. These may be used in any desired mixing ratio. In particular, the metal may be a transition metal, such as tungsten or molybdenum, or a mixture of these in any mixing ratio. Optionally, the metal or metalloid may be molybdenum. In case that the metal is a transition metal the process of the invention produces preferably transition metal dichalcogenides. Molybdenium and Tungsten dichalcogenieds or their mixtures can be especially mentioned. In one embodiment, the sputtering target may include, but is not limited to, elemental molybdenum.

The chalcogen may include, but is not limited to, sulphur, selenium and tellurium or mixtures thereof. These elements may have the advantage, that they produce a desirable band gap and therefore provide for the application of such coated substrates in, for example, field effect transistor devices.

In one embodiment, the chalcogen may be sulphur. The preferred chalcogenide can then be MoS₂.

The sulphur may be provided in the form of a powder for vaporization. This powder may be stored in a reservoir, wherein it is getting vaporized and, through a leaking valve, reach the deposition chamber. The growth rate of the metal or metalloid chalcogenide is, inter alia, dependant on the partial pressure of vaporized chalcogen. Therefore, it is understood, that the heating temperature of the reservoir may be adjusted depending on the chalcogen used. Vaporizing of the sulphur is preferably done in a controlled manner. For controlling the vaporization typical valves combined with an RGA can be used.

There is provided the use of the process to create one or multiple 2D monolayers of the transitional chalcogenide on a substrate. Preferably, one, two, three, four, five, six or seven layers are deposited with well-defined structure.

There is provided a metal or metalloid chalcogenide obtainable by the process as defined above. The chalcogenide monolayers obtainable by the process have an organized structure of uniformity, although showing the presence of more lattice disorder or residual dopants than mechanically exfoliated monolayers. They are new materials for use in the applications mentioned throughout the description.

In one embodiment there is provided the use of the metal or metalloid chalcogenide as defined above in a layered semiconductor device, such as a field effect transistor. A thin layer of dichalcogenide is for instance well suited as a channel material in field effect transistors (FETs), exhibiting high mobility, almost ideal switching characteristics and low standby power dissipation.

There is provided use of the metal or metalloid chalcogenide as disclosed above in nanoelectronics, as a catalyst, as a photo-detector, photovoltaic or photocatalyst.

The photovoltaic or photocatalyst may be used in the range of visible light to near-infrared applications, preferably it may be used under visible light conditions.

### BRIEF DESCRIPTION OF DRAWINGS

The accompanying drawings illustrate a disclosed embodiment and serves to explain the principles of the disclosed embodiment. It is to be understood, however, that the drawings are designed for purposes of illustration only, and not as a definition of the limits of the invention.

FIG. 1 is a schematic drawing of an example of the apparatus suitable for the disclosed process.

FIG. 2 shows the core level spectra of X-ray photoelectron spectroscopy (XPS).

FIG. 3 shows a high-resolution X-ray diffraction result for MoS2 film grown as compared to the bulk materials.

FIG. 4 shows a Raman spectrum of a few-layer large scale MoS2.

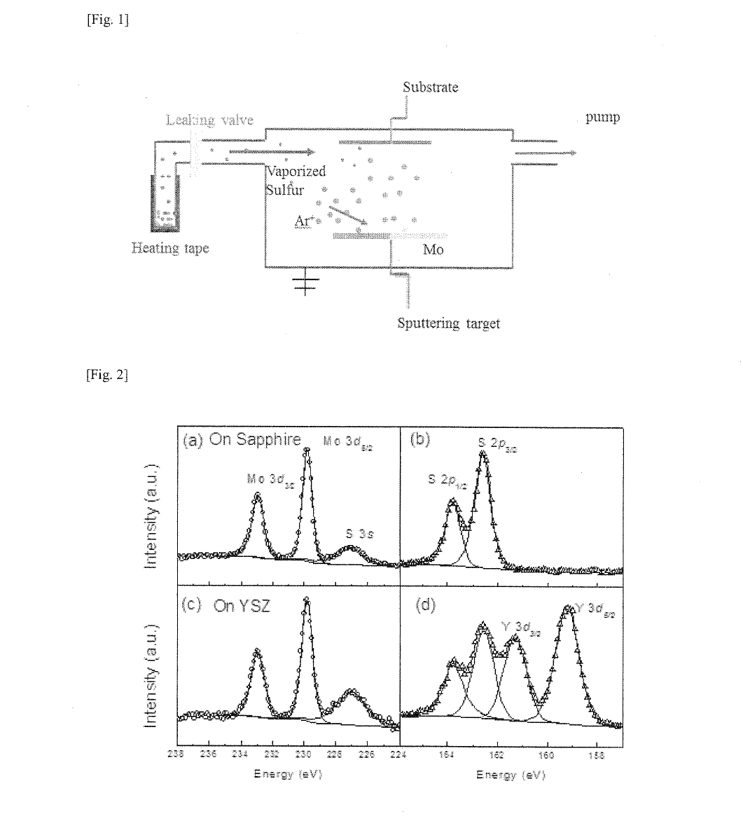

### EXAMPLES

Non-limiting examples of the invention and a comparative example will be further described in greater detail by reference to specific examples, which should not be construed as in any way limiting the scope of the invention.

### Example

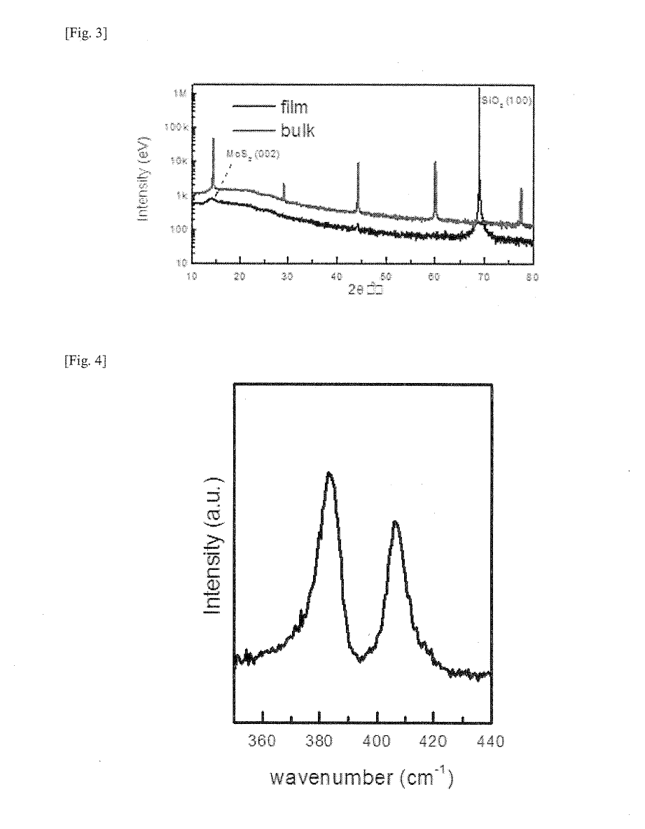

The magnetron sputtering of molybdenum is carried out in a vaporized sulphur ambient. The sputtering gun is a Torus magnetron sputtering (TM3u) from K. J Lesker. The target is molybdenum (99.9% from Able Target). The chalcogenide is sulphur (99.5% sulphur powder, purchased from Sigma Aldrich). The power source is DC power. The substrates were pre-cleaned using acetone in an ultrasonic bath before introducing to the deposition chamber. The deposition was performed with a substrate temperature of 700° C. Sulphur powder was heated up above 250° C. by wrapped heating tape to obtain the desired sulphur partial pressure, 4.0×10⁻⁷ mbar in the present system. The argon pressure is fixed at 6.0×10⁻⁴ mbar. Both partial pressures were measured and monitored by RGA CIS 200 from SRS. The DC power is kept as low as 6 W for low growth rate. Using this process, few layers of MoS₂ can be grown on variable substrates, such as sapphire, yttria-stabilized zirconia (YSZ), amorphous SiO₂ and Si etc. To demonstrate the process, few layers of MoS₂ were first grown on c-plane sapphire [Al₂O₃(0001)] and YSZ(111). The out-of-plane orientation of MoS₂ film was determined to be (0001) by high-resolution x-ray diffraction (HR-XRD), recorded on a PANalytical X′pert pro with step size 0.1 degree, dwell time 0.2 second, and a range of 10-80 degree. FIG. 2 shows the core-level XPS spectra of Mo 3d and S 2p on MoS₂/Sapphire, and MoS₂/YSZ systems, recorded on a VG ESCALAB 220i-XL with monochromated X-Ray and 10 eV pass energy to achieve high resolution. As shown in FIG. 2 (a) and (c), the Mo 3d spectra on both substrates are almost identical, which can be fitted using two components at 229.81 and 232.94 eV, respectively, in agreement with reported values. As shown in FIG. 2 (b) and (d), the spin-orbital splitting for S 2p is well resolved which suggest the good film quality. On YSZ, the lower binding energy peaks at 161.31 eV and 159.21 eV come from the Y 3d_{3/2} and 3d_{5/2} orbitals. The atomic ratio between Mo and S is determined to be 1:2 from quantitatively analysis of XPS peaks. In addition, HR-XRD was used and the crystal structure is of the film confirmed to be 2H—MoS₂ phase on both substrates. In this phase, each Mo atom is prismatically coordinated by six surrounding S atoms and it exhibits semiconducting behaviour. As shown below by HR-XRD, (FIG. 3) and Raman spectrum (FIG. 4), the films can be grown on variable substrates with the c-axis of MoS₂ perpendicular to the substrate surface. All these results demonstrate that the films exhibit correct phase and they are in good quality Raman spectra were obtained on a single-gating micro-Raman spectrometer (Horiba-JY T64000) excited with 532 nm laser. The signal was collected through a 100× objective, dispersed with a 1800 g/mm grating, and detected by a liquid nitrogen cooled charge-coupled device. Photoluminescence (PL) was obtained from the same micro-Raman spectrometer. The Si peak at 520 cm ⁻¹ was used for calibration in the experiments.

This process can be easily applied to other metal or metalloid dichalcogenide film growth by switching the target between, for example, molybdenum and tungsten, and switching the vapor source between, for example, sulphur and selenium.

### INDUSTRIAL APPLICABILITY

The process for the production of metal or metalloid chalcogenides described in this disclosure may be useful as a facile and low-cost procedure for a high-yield preparation of the materials. Such metal or metalloid chalcogenides have a direct band gap, and can be used in electronics as transistors and in optics as emitters and detectors. The metal or metalloid chalcogenide monolayer crystal structure has no inversion center, which allows to access a new degree of freedom of charge carriers, namely the k-valley index, and to open up a new field of physics: valleytronics.

The strong spin-orbit coupling in metal or metalloid chalcogenide monolayers lead to a spin-orbit splitting of hundreds meV in the valence band and a few meV in the conduction band, which allows control of the electron spin by tuning the excitation laser photon energy.

The work on metal or metalloid chalcogenide monolayers is an emerging research and development field since the discovery of the direct bandgap and the potential applications of the very peculiar electron valley physics. The process according to the invention provides a new method for producing such monolayers on larger areas and is therefore suited for mass fabrication of the materials.

It will be apparent that various other modifications and adaptations of the invention will be apparent to the person skilled in the art after reading the foregoing disclosure without departing from the spirit and scope of the invention and it is intended that all such modifications and adaptations come within the scope of the appended claims.

1. A process for making metal or metalloid chalcogenides from a metal or metalloid and an elemental chalcogen using magnetron sputtering, wherein the process involves a chemical reaction between the ejected metal or metalloid atoms and the elemental chalcogen.

2. The process of claim 1 wherein the process is a one-step process.

3. The process of claim 1 comprising:
a) directing sputtering gas ions at a target comprising a metal or metalloid
b) reacting the ejected metal or metalloid atoms from the target surface with an elemental chalcogen vapor and
c) assembling the metal or metalloid chalcogenides on a substrate. cm 4. The process of claim 1, wherein sputtering is performed in an apparatus comprising:
(i) a vacuum deposition chamber
ii) a sputtering target comprising the metal or metalloid
iii) a reservoir of elemental chalcogen optionally linked to a vaporizer
iv) a power source to effect ejection of the metal or metalloid atoms,
v) a substrate on which the deposition of the metal or metalloid chalcogenide occurs.

5. The process of claim 1, wherein the process is performed using a substrate for assembling the chalcogenide which heated to temperature of between about 300° C. and 1000° C.

6. The process of claim 1, wherein the chalcogen is vaporized by heating.

7. The process of claim 6, wherein the heating of the chalcogen is performed by using wrapped heating tape.

8. The process of any of claim 6, wherein the vaporized chalcogen produces a partial pressure of about 1.0 to 9.0×10−7 mbar.

9. The process of any of claim 1, wherein a sputtering gas is used.

10. The process of claim 9, wherein the sputtering gas is provided with a fixed pressure of about 1.0×10⁻⁴ to 3.0×10⁻³ mbar.

11. The process of claim 9, wherein the sputtering gas comprises an inert gas.

12. The process of claim 11, wherein the inert gas comprises argon.

13. The process of claim 1, wherein the power source to effect ejection of the metal or metalloid atoms comprises a DC power and a RF power source.

14. The process of claim 13, wherein the power source to effect ejection of the metal or metalloid atoms comprises a DC power.

15. The process of claim 14, wherein the DC power source with a power of less than 10 W is used for the sputtering.

16. The process of claim 1, wherein a substrate is used which is cleaned prior to the sputtering process.

17. The process of claim 16, wherein the cleaning involves using acetone in an ultrasonic bath.

18. The process of claim 1, wherein a substrate is used which comprises materials from the group consisting of glass, silicon, silicon oxides, metal, metal alloy, metal oxides and any mixture thereof.

19. The process of claim 1, wherein the substrate comprises silicon or silicon oxide, optionally in amorphous phase and optionally hafnia-stabilized.

20. The process of claim 18, wherein the substrate comprises aluminum oxide.

21. The process of claim 18, wherein the substrate comprises zirconia.

22. The process of claim 1, wherein the metal or metalloid chalcogenide is deposited as a film on a substrate.

23. The process of claim 22, wherein the film comprises one or multiple monolayers of the metal or metalloid chalcogenides.

24. The process of claim 23, wherein the film has a thickness of about 0.5 to 10 nm.

25. The process of claim 1, wherein the metal or metalloid has an oxidation state of +4 and the atomic ratio between the metal or metalloid and the chalcogen is between about 1:1.75 to 2.05.

26. The process of claim 25, wherein in the metal or metalloid chalcogenide, the metal or metalloid is prismatically coordinated by six surrounding chalcogen atoms and the c-axis is perpendicular to the substrate used in the process.

27. The process of claim 22, wherein the metal or metalloid chalcogenide has semi-conducting properties.

28. The process of claim 1, wherein the metal or metalloid comprises a transition metal.

29. The process of claim 28, wherein the transition metal comprises aluminium, chromium, copper, tungsten and molybdenum.

30. The process of claim 28, wherein the transition metal comprises a metal that is selected from tungsten, molybdenum or a mixture thereof.

31. The process of claim 30, wherein the transition metal comprises molybdenum.

32. The process of claim 1, wherein a sputtering target is used that comprises elemental molybdenum.

33. The process of claim 1, wherein the metal or metalloid chalcogenide comprises a transition metal dichalcogenide.

34. The process of claim 1, wherein the chalcogen comprises sulphur, selenium, tellurium or a mixture thereof.

35. The process of claim 34, wherein the chalcogen comprises sulphur.

36. The process of claim 1, wherein the chalcogen is provided in the form of a powder for vaporization.

37. Creating one or multiple 2D monolayers of the transitional chalcogenide on a substrate by using a process for making metal or metalloid chalcogenides from a metal or metalloid and an elemental chalcogen using magnetron sputtering, wherein the process involves a chemical reaction between the ejected metal or metalloid atoms and the elemental chalcogen.

38. A metal or metalloid chalcogenide obtainable by a process for making metal or metalloid chalcogenides from a metal or metalloid and an elemental chalcogen using magnetron sputtering, wherein the process involves a chemical reaction between the ejected metal or metalloid atoms and the elemental chalcogen.

39. A metal or metalloid chalcogenide in a layered semiconductor device, wherein the metal or metalloid chalcogenide is obtainable by a process for making metal or metalloid chalcogenides from a metal or metalloid and an elemental chalcogen using magnetron sputtering, wherein the process involves a chemical reaction between the ejected metal or metalloid atoms and the elemental chalcogen.

40. A metal or metalloid chalcogenide in nanoelectronics, wherein the metal or metalloid chalcogenide is obtainable by a process for making metal or metalloid chalcogenides from a metal or metalloid and an elemental chalcogen using magnetron sputtering, wherein the process involves a chemical reaction between the elected metal or metalloid atoms and the elemental chalcogen, wherein the metal or metalloid chalcogenide acts as a catalyst, a photo-detector, a photovoltaic or photocatalyst.

41. The metal or metalloid chalcogenide in nanoelectronics of claim 40, wherein the photovoltaic or photocatalyst can be used under visible light conditions.
